(19) United States
(12) Patent Application Publication
(10) Pub. No.: US 2014/0366807 A1
(43) Pub. Date: Dec. 18, 2014

(54) APPARATUS FOR FABRICATING INGOT AND METHOD OF FABRICATING INGOT

(71) Applicants: Ji Hye Kim, Seoul (KR); Chang Hyun Son, Seoul (KR)

(72) Inventors: Ji Hye Kim, Seoul (KR); Chang Hyun Son, Seoul (KR)

(73) Assignee: LG INNOTEK CO., LTD., Seoul (KR)

(21) Appl. No.: 14/369,112

(22) PCT Filed: Jul. 10, 2012
(86) PCT No.: PCT/KR2012/005455

§ 371 Date: Aug. 11, 2014

(30) Foreign Application Priority Data
Dec. 26, 2011 (KR) 10-2011-0142889

(51) Int. Cl. C30B 23/02

(52) U.S. Cl. CPC C30B 23/02
USPC 118/728

(57) ABSTRACT

Disclosed is an apparatus for fabricating an ingot, and a method of fabricating the ingot. The apparatus includes a crucible to receive a raw material, and a holder to fix a seed positioned on the raw material. The holder fixes a plurality of seeds.

### TECHNICAL FIELD

The disclosure relates to an apparatus for fabricating an ingot and a method of fabricating the ingot.

### BACKGROUND ART

In general, materials are very important factors to determine the property and the performance of final products in the electric, electronic and mechanical industrial fields.

SiC represents the superior thermal stability and superior oxidation-resistance property. In addition, the SiC has the superior thermal conductivity of about 4.6 W/Cm?, so the SiC can be used for fabricating a large-size substrate having a diameter of about 2 inches or above. In particular, the single crystal growth technology for the SiC is very stable actually, so the SiC has been extensively used in the industrial field as a material for a substrate.

In the case of SiC, a scheme of growing the single crystal for SiC has been suggested through a seeded growth sublimation scheme. In this case, after putting a SiC powder serving as a raw material in a crucible, a SiC single crystal serving as a seed is provided on the raw material. Temperature gradient is formed between the raw material and the seed, so that the raw material in the crucible is dispersed to the seed, and re-crystallized to grow a single crystal.

When growing the single crystal, long time of about 70 hours or more is spent, so that the product yield of the single crystal may be lowered. In addition, if the rate of growing the single crystal is increased in order to increase the product yield of the single crystal, the quality of the single crystal may be lowered.

### DISCLOSURE OF INVENTION

### Technical Problem

The embodiment can grow a high-quality single crystal and improve the product yield of the single crystal.

### Solution to Problem

According to the embodiment, there is provided an apparatus for fabricating an ingot. The apparatus includes a crucible to receive a raw material, and a holder to fix a seed positioned on the raw material. The holder fixes a plurality of seeds.

### Advantageous Effects of Invention

As described above, according to an apparatus of fabricating an ingot, a plurality of seeds can be provided. Since the plural seeds are provided, the product yield can be increased. In addition, the effect of the diameter expansion of the single crystal may be obtained or the predetermined shape for mass production may be maintained according to the shapes of the guide members.

### BRIEF DESCRIPTION OF DRAWINGS

FIG. 1 is a sectional view showing an apparatus for fabricating an ingot according to the embodiment;

FIG. 2 is a view showing the coupling of a seed holder, a seed, and a guide member constituting the apparatus for fabricating the ingot according to the embodiment; and

FIG. 3 is a view showing the coupling of the guide member and the coupling member constituting the apparatus for fabricating the ingot according to the embodiment.

### MODE FOR THE INVENTION

In the description of the embodiments, it will be understood that, when a layer (or film), a region, a pattern, or a structure is referred to as being “on” or “under” another layer (or film), another region, another pad, or another pattern, it can be “directly” or “indirectly” on the other layer (or film), region, pad, or pattern, or one or more intervening layers may also be present. Such a position of the layer has been described with reference to the drawings.

The thickness and size of each layer (film), region, pattern, or structure shown in the drawings may be exaggerated, omitted or schematically drawn for the purpose of convenience or clarity. In addition, the size of each layer (film), region, pattern, or structure does not utterly reflect an actual size.

Hereinafter, the embodiment of the present invention will be described in detail with reference to accompanying drawings.

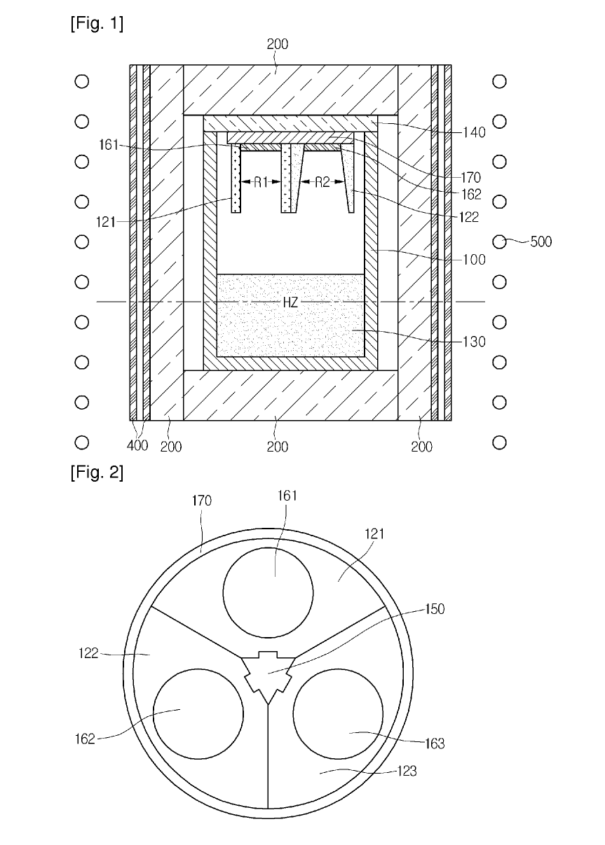

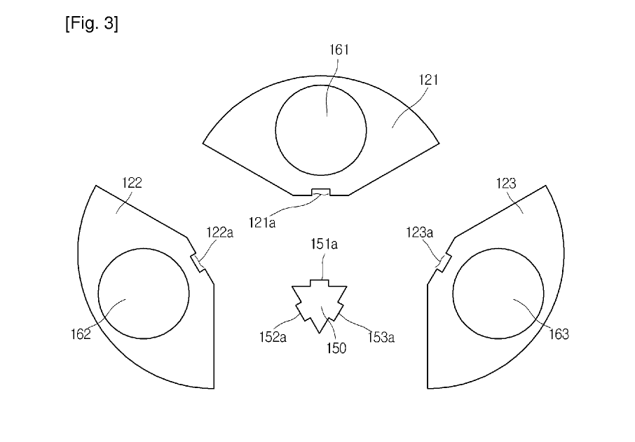

Hereinafter, an apparatus for fabricating an ingot according to the embodiment will be described in detail with reference to FIGS. 1 to 3. FIG. 1 is a sectional view showing the apparatus for fabricating the ingot according to the embodiment. FIG. 2 is a view showing the coupling of a seed holder, a seed, and a guide member constituting the apparatus for fabricating the ingot according to the embodiment, and FIG. 3 is a view showing the coupling of the guide member and the coupling member constituting the apparatus for fabricating the ingot according to the embodiment.

Referring to FIGS. 1 to 3, the apparatus for fabricating the ingot includes a crucible 100, guide members 121, 122, and 123, a coupling member 150, an upper cover 140, a seed holder 170, an adiabatic material 300, a quartz tube 400, and a heat induction part 500.

The crucible 100 receives raw materials 130 therein.

The crucible 100 has a cylindrical shape to receive the raw materials 130.

The crucible 100 may include a material having the melting point higher than the sublimation temperature of the SiC.

For example, the crucible 100 can be manufactured by using graphite.

In addition, the crucible 100 can be manufactured by coating a material having the melting point higher than the sublimation temperature of the SiC on the graphite. Preferably, a material, which is chemically inert with respect to silicon and hydrogen at the growth temperature for the SiC single crystal, is used as the material coated on the graphite. For instance, the material may include metal carbide or nitride carbide. In particular, a mixture including at least two of Ta, Hf, Nb, Zr, W and V and carbide including carbon can be coated on the graphite. Further, a mixture including at least two of Ta, Hf, Nb, Zr, W and V and nitride including nitrogen can be coated on the graphite.

The raw materials 130 may include silicon and carbon. In detail, the raw materials 130 may include a silicon carbide compound. The crucible 100 may receive SiC powders or polycarbosilane.

A top cover 140 is positioned at the upper portion of the crucible 100. The top cover 140 can seal the crucible 100. In detail, the top cover 140 may seal the crucible 100 so that reaction can occur in the crucible 100.

The upper cover 140 may include graphite. However, the embodiment is not limited thereto, and the upper cover 140 may include a material having a melting point greater than or equal to the sublimation temperature of SiC.

The seed holder 170 is located at a lower end of the top cover 140. The seed holder 170 is provided on the raw material 130.

The seed holder 170 can fix seeds 161, 162, and 163 thereto. The seed holder 170 may include high-concentration graphite. In particular, the seed holder 170 may fix the seeds 161, 162, and 163 thereto.

The seeds 161, 162, and 163 are attached to the seed holder 170. Accordingly, an ingot can be prevented from being grown to the upper cover 140 by attaching the seeds 161, 162, and 163 to the seed holder 170. However, the embodiment is not limited thereto, and the seeds 161, 162, and 163 may be directly attached to the upper cover 140.

A plural of seeds 161, 162, and 163 may be provided. For example, the seeds 161, 162, and 163 may include the first seed 161, the second seed 162, and the third seed 163. The first seed 161, the second seed 162, and the third seed 163 may be aligned in line with each other. In other words, the first to third seeds 161, 162, and 163 may be provided on the bottom surface of the seed holder 170.

The guide members 121, 122, and 123 may be provided in the crucible 100. The guide member 121, 122, and 123 may be provided on the raw material 130. The guide members 121, 122, and 123 may extend the length direction of the crucible 100.

The guide members 121, 122, and 123 may be provided along the inner lateral side of the crucible 100.

The guide members 121, 122, and 123 may be provided adjacent to the seeds 161, 161, and 163. In more detail, the guide members 121, 122, and 123 may surround the seeds 161, 162, and 163.

The guide members 121, 122, and 123 may have the shape of a ring having an inner diameter and an outer diameter.

A plurality of guide members 121, 122, and 123 may be provided. In more detail, the guide members 121, 122, and 123 may be provided corresponding to the number of the seeds 161, 162, and 163. For example, when the apparatus for fabricating the ingot according to the embodiment includes the first seed 161, the second seed 162, and the third seed 163, the guide members 121, 122, and 123 may include the first guide member 121, the second guide member 122, and the third guide member 123. The first guide member 212, the second guide member 122, and the third guide member 123 may be positioned in line with each other on the bottom surface of the seed holder 170. The first to third guide members 121 to 123 may be positioned adjacent to each other.

Referring to FIG. 2, the first guide member 121 may surround the first seed 161. The second guide member 122 may surround the second seed 162. The third guide member 123 may surround the third seed 163.

Since the guide members 121, 122, and 123 surround the seeds 161, 162, and 163, respectively, the single crystals grown from the seeds 161, 162, and 163 can be prevented from being bonded to each other. In other words, the single crystals can be grown from the seeds 161, 162, and 163 while maintaining the shapes of the single crystals.

The guide members 121, 122, and 123 may have various shapes. For example, as shown in FIG. 1, the first guide member 121 may have a constant inner diameter. In other words, since the inner diameter of the first guide member 121 is constant, the shape of the single crystal grown from the first seed 161 may be constantly maintained. In addition, referring to FIG. 1, the inner diameter of the second guide member 122 may be reduced toward the upper portion of the crucible 100. In other words, the inner diameter of the second guide member 122 may be increased toward the lower portion of the crucible 100. Accordingly, the diameter of the crystal grown from the seed 162 may be enlarged. However, the embodiment is not limited thereto, and the inner diameter of the first guide member 121 is reduced toward the upper portion of the crucible 100, and the inner diameter of the second guide member 122 may have a constant shape. In addition, although not shown in drawings, the diameter of the third guide member 123 may be varied according to the single crystal to be grown from the third seed 163.

According to the embodiment, the seeds 161, 162, and 163 include a plurality of seeds, so that the product yield can be increased. In addition, the effect of the diameter expansion of the single crystal may be obtained or the predetermined shape for mass production may be maintained according to the shapes of the guide members 121, 122, and 123.

Thereafter, the coupling member 150 may be positioned in the first to third guide members 121 to 123. The coupling member 150 may connect the first to third guide members 121 to 123 to each other.

Referring to FIG. 3, the coupling member 150 may include protrusions 151a, 152a, and 153a, and the guide members 121, 122, and 123 may include grooves 121a, 122a, and 123a. Accordingly, the protrusions 151a, 152a, and 153a are coupled with the grooves 121a, 122a, and 123a, so that the guide members 121, 122, and 123 can be stably coupled with each other. In more detail, the coupling member 150 may include the first to third protrusions 151a, 152a, and 153a. In addition, the first guide member 121 may include the first groove 121a, the second guide member 122 may include the second groove 122a, and the third guide member 123 may include the third groove 123a. The first protrusion 151a may be coupled with the first groove 121a, and the second protrusion 152a may be coupled with the second groove 122a. The third protrusion 153a may be coupled with the third groove 123a.

The number of the protrusions 151a, 152a, and 153a of the coupling member 150 may be varied according to the number of the guide members 121, 122, and 123.

The guide members 121, 122, and 123 include pores. The guide members 121, 122, and 123 may have a porous structure. The guide members 121, 122, and 123 may have porosity in the range of about 30% to 70%. If the porosity of the guide members 121, 122, and 123 is less than 30%, an adiabatic function may be degraded. In addition, if the porosity of the guide members 121, 122, and 123 exceed 70%, the durability of the guide members 121, 122, and 123 may be degraded.

The guide members 121, 122, and 123 may include a high temperature resistance material. This is because the guide members 121, 122, and 123 are positioned in the crucible 100. For example, the guide members 121, 122, and 123 may include graphite.

The guide members 121, 122, and 123 can prevent the heat of the crucible 100 from exerting an influence on the seed holder 170 and the edges of the seeds 161, 162, and 163. In other words, the guide members 121, 122, and 123 can prevent heat from being transferred to the edges of the single crystals grown from the seeds 161, 162, and 163.

Therefore, the difference in the temperature between a central portion CA of the seeds 161, 162, and 163, and the outer portion of the seeds 161, 162, and 163 can be reduced. In other words, the temperature of the seeds 161, 162, and 163 may be uniformly maintained. Therefore, the stress and the defects in the outer portions of the seeds 161, 162, and 163 can be minimized. In addition, the central portion of the single crystals grown from the seeds 161, 162, and 163 does not have a convex shape formed due to the difference in the temperature between the central portion CA of the seeds 161, 162, and 163 and the outer portion of the seeds 161, 162, and 163. Therefore, the single crystal can be more effectively used.

The adiabatic material 200 surrounds the crucible 100. The adiabatic material 200 keeps the temperature of the crucible 100 to the level of the crystal growth temperature. Since the crystal growth temperature of the SiC is high, graphite felt may be used as the adiabatic material 200. In detail, the adiabatic material 200 may include a cylindrical graphite felt having a predetermined thickness prepared by compressing graphite fiber. In addition, the adiabatic material 200 may be prepared as a plurality of layers surrounding the crucible 100.

The quartz tube 400 is positioned at an outer peripheral surface of the crucible 100. The quartz tube 400 is fitted around the outer peripheral surface of the crucible 100. The quartz tube 400 may block heat transferred into a single crystal growth apparatus from the heat induction part 500. The quartz tube 400 is a hollow tube and cooling water may circulate through an inner space of the quartz tube 400. Accordingly, the quartz tube 400 can more exactly control the growing speed and the growing size of the single crystal.

The heat induction part 500 is positioned outside the crucible 100. For instance, the heat induction part 500 is an RF induction coil. As RF current is applied to the RF induction coil, the crucible 100 can be heated. That is, the raw materials contained in the crucible 100 can be heated to the desired temperature.

The center area of the heat induction part 500 is located below the center area of the crucible 100. Thus, the temperature gradient may occur at the upper and lower portions of the crucible 100. That is, the center area (hot zone; HZ) of the heat induction part 500 is located relatively lower than the center area of the crucible 100, so the temperature of the lower portion of the crucible 100 may be higher than the temperature of the upper portion of the crucible 100 on the basis of the hot zone HZ. In addition, the temperature may rise from the center of the crucible 100 to the outer peripheral portion of the crucible 100. Due to the temperature gradient, the SiC raw materials may be sublimated so that the sublimated SiC gas moves to the surface of the seeds 161, 162, and 163 having the relatively low temperature. Thus, the SiC gas is re-crystallized, so the SiC single crystal is grown.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. An apparatus for fabricating an ingot, the apparatus comprising:
a crucible to receive a raw material; and
a holder to fix a seed positioned on the raw material,
wherein the holder fixes a plurality of seeds.

2. The apparatus of claim I, further comprising a guide member adjacent to the seed.

3. The apparatus of claim 2, wherein the guide member surrounds the seed.

4. The apparatus of claim 3, wherein the guide member has a shape of a ring having an inner diameter and an outer diameter.

5. The apparatus of claim 4, wherein the inner diameter is reduced toward an upper portion of the crucible.

6. The apparatus of claim 4, wherein the inner diameter is constant.

7. The apparatus of claim 3, wherein the seed comprises first and second seeds.

8. The apparatus of claim 7, wherein the first seed is aligned in line with the second seed.

9. The apparatus of claim 7, wherein the guide member comprises a first guide member surrounding the first seed, and a second guide member surrounding the second seed.

10. The apparatus of claim 9, wherein the seed further comprises a third seed, and a third guide member is additionally provided to surround the third seed.

11. The apparatus of claim 9, wherein the first guide member comprises a first groove, and the second guide member comprises a second groove.

12. The apparatus of claim 11, further comprising a coupling member to couple the first guide member to the second guide member.

13. The apparatus of claim 12, wherein the coupling member is provided in the first and second grooves.

14. The apparatus of claim 13, wherein the coupling member comprises first and second protrusions, the first protrusion is coupled with the first groove, and the second protrusion is coupled with the second groove.

15-17. (canceled)

18. The apparatus of claim 2, wherein the guide member extends in the length direction of the crucible.

19. The apparatus of claim 9, wherein the first guide member and the second guide member are positioned in line with each other on the bottom surface of the seed holder.

20. The apparatus of claim 2, wherein the guide member includes pores.

21. The apparatus of claim 20, wherein the guide member has porosity in the range of about 30% to about 70%.

22. The apparatus of claim 2, wherein the crucible and the guide member comprise a same material.

23. The apparatus of claim 22, wherein the crucible and the guide member comprise graphite.
